(19) United States
(12) Patent Application Publication
(10) Pub. No.: US 2026/0196262 A1
(43) Pub. Date: Jul. 9, 2026

(54) MEMORY DEVICE INCLUDING PLURALITY OF MEMORY CELLS

(71) Applicant: SAMSUNG ELECTRONICS CO., LTD., Suwon-si (KR)

(72) Inventors: Hyunjun Kim, Suwon-si (KR); Seong-ook Jung, Seoul (KR); Yeongtak Han, Seoul (KR); Giseok Kim, Seoul (KR)

(73) Assignees: SAMSUNG ELECTRONICS CO., LTD., Suwon-si (KR); UIF (University-Industry Foundation) Yonsei University, Seoul (KR)

(21) Appl. No.: 19/429,055

(22) Filed: Dec. 22, 2025

(30) Foreign Application Priority Data
Jan. 8, 2025 (KR) 10-2025-0003103

(51) Int. Cl. G11C 11/419; G11C 11/412; G11C 11/418

(52) U.S. Cl. CPC G11C 11/419; G11C 11/412; G11C 11/418

(57) ABSTRACT

A memory device may include a memory cell array including a plurality of memory cells, and a controller connected to the memory cell array. A first memory cell among the plurality of memory cells includes a first inverter including a first PMOS transistor, and a first NMOS transistor connected between the first PMOS transistor and a ground, a second inverter including a second NMOS transistor, and a second PMOS transistor connected between the second NMOS transistor and a power supply voltage, a write buffer that generates first data, based on a first enable signal output from the first inverter and a second enable signal output from the second inverter, and a latch circuit that stores the first data. In a write operation on the first memory cell, the controller is configured to apply a first column selection signal to a source-drain electrode of the first PMOS transistor.

### CROSS-REFERENCE TO RELATED APPLICATION

This application is based on and claims priority under 35 U.S.C. § 119 to Korean Patent Application No. 10-2025-0003103 filed on January 8, 2025, in the Korean Intellectual Property Office, the disclosures of which are herein incorporated by reference in their entireties.

### BACKGROUND

Embodiments of the present disclosure relate to a memory device including a plurality of memory cells.

A semiconductor device such as a machine learning accelerator or a central processing unit (CPU) may include a static random access memory (SRAM) which is used as a cache memory or a buffer memory.

To improve a computational speed of the semiconductor device, a memory may include a plurality of memory cells having a relatively small capacity. In addition, to increase area efficiency, each memory cell may be implemented based on a standard cell rather than a six-transistor (6T) SRAM cell.

Also, as a structure of a transistor constituting the memory cell changes from a planar structure to a three-dimensional (3D) structure, a capacitance of a gate electrode of the transistor increases, and a diffusion capacitance decreases.

### SUMMARY

Embodiments of the present disclosure provide a memory device capable of improving power efficiency of a write operation on a memory cell.

According to an embodiment, a memory device may include a memory cell array including a plurality of memory cells, and a controller connected to the memory cell array. A first memory cell among the plurality of memory cells may include a first inverter including a first PMOS transistor, and a first NMOS transistor connected between the first PMOS transistor and a ground, a second inverter including a second NMOS transistor, and a second PMOS transistor connected between the second NMOS transistor and a power supply voltage, a write buffer that generates first data, based on a first enable signal output from the first inverter and a second enable signal output from the second inverter, and a latch circuit that stores the first data. In a write operation on the first memory cell, the controller may be configured to apply a first column selection signal to a source-drain electrode of the first PMOS transistor.

According to an embodiment, a memory cell may include a first inverter including a first PMOS transistor, and a first NMOS transistor connected between the first PMOS transistor and a ground, a second inverter including a second NMOS transistor, and a second PMOS transistor connected between the second NMOS transistor and a power supply voltage, a write buffer that generates first data, based on a first enable signal output from the first inverter and a second enable signal output from the second inverter, and a latch circuit that stores the first data, based on the first enable signal and the second enable signal. The first inverter may be configured to output the first enable signal, in response to a first column selection signal and an inverse row selection signal, and the first column selection signal may be applied through a source-drain electrode of the first PMOS transistor.

According to an embodiment, a memory device may include a first memory cell, and a controller electrically connected to the first memory cell. The first memory cell may include a first inverter including a first PMOS transistor, and a first NMOS transistor connected between the first PMOS transistor and a ground, a second inverter including a second NMOS transistor, and a second PMOS transistor connected between the second NMOS transistor and a power supply voltage, a write buffer that generates first data, based on a first enable signal output from the first inverter and a second enable signal output from the second inverter, and a latch circuit that stores the first data. In a write operation on the first memory cell, the controller may be configured to apply a first column selection signal to a source-drain electrode of the first PMOS transistor and may be configured to apply a second column selection signal to a source-drain electrode of the second NMOS transistor.

### BRIEF DESCRIPTION OF FIGURES

The above and other objects and features of the present disclosure will become apparent by describing in detail embodiments thereof with reference to the accompanying drawings.

FIG. 1 is a block diagram of a memory device according to an embodiment of the present disclosure.

FIG. 2 is a circuit diagram of a first memory cell according to an embodiment.

FIG. 3 illustrates signals generated in a write operation on a first memory cell according to an embodiment.

FIG. 4 illustrates a configuration in which first data are stored in a first memory cell according to an embodiment.

FIG. 5 is a circuit diagram of a first memory cell further including a read buffer according to an embodiment.

FIG. 6 illustrates signals generated in a read operation on a first memory cell according to an embodiment.

FIG. 7 illustrates a configuration in which first data stored in a first memory cell are output through a read buffer according to an embodiment.

FIG. 8 illustrates a layout of a first memory cell according to an embodiment.

### DETAILED DESCRIPTION

Below, example embodiments of the present disclosure will be described in detail and clearly to such an extent that one skilled in the art easily carries out the present disclosure.

In the present disclosure, the expressions “first”, “second”, etc. may modify various components regardless of the order and/or the importance, are only used to distinguish one component from another component, and are not intended to limit the order or importance of components.

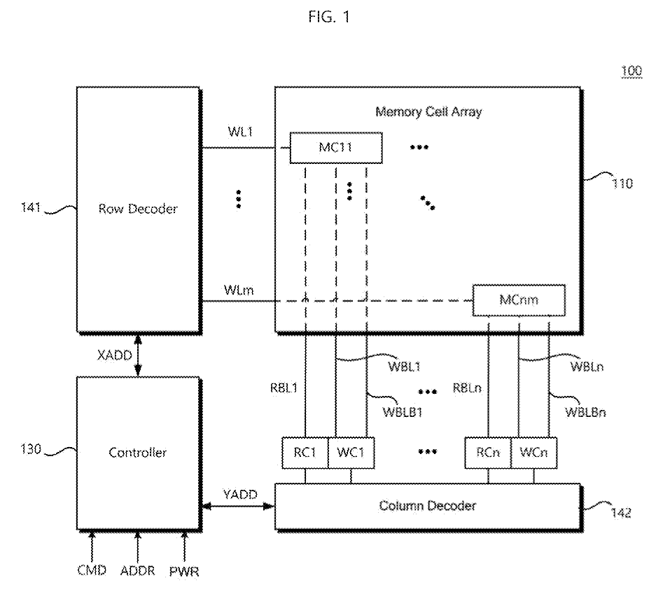

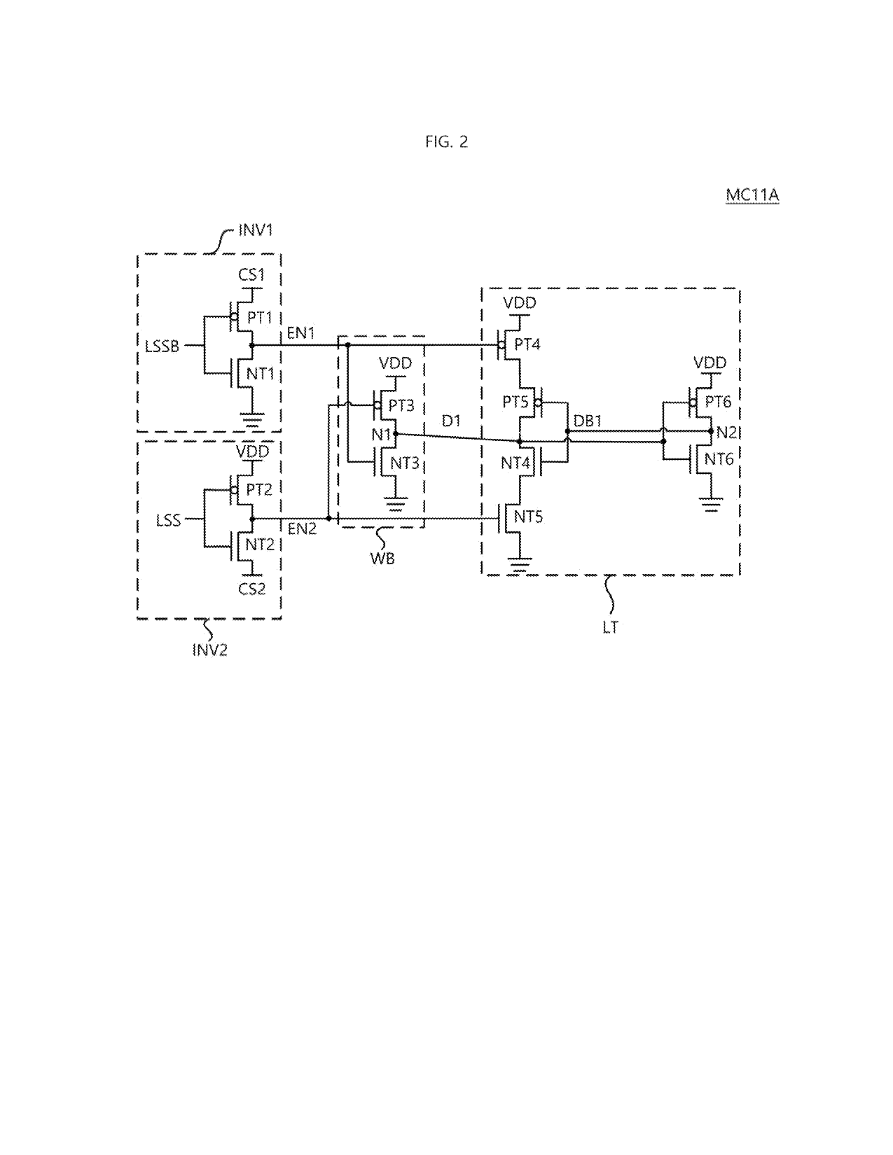

FIG. 1 is a block diagram of a memory device according to an embodiment of the present disclosure. FIG. 2 is a circuit diagram of a first memory cell according to an embodiment.

Referring to FIG. 1, a memory device 100 according to an embodiment may include a memory cell array 110, a controller 130, a row decoder 141, and a column decoder 142.

According to an embodiment, the memory device 100 may include the memory cell array 110 including a plurality of memory cells MC11 to MCnm (each of m and n being a natural number). For example, the memory cell array 110 may include the plurality of memory cells MC11 to MCnm each implemented with a static random access memory (SRAM) cell.

The memory cell array 110 according to an embodiment may include the plurality of memory cells MC11 to MCnm arranged in a shape of a matrix having rows and columns. Herein, the plurality of memory cells MC11 to MCnm may be connected to a plurality of word lines WL1 to WLm, a plurality of read bit lines RBL1 to RBLm, a plurality of first write bit lines WBL1 to WBLn, and a plurality of second write bit lines WBLB1 to WBLBn.

For example, a first memory cell MC11 may be connected to a first word line WL1, a first read bit line RBL1, a (1-1)-th write bit line WBL1, and a (2-1)-th write bit line WBLB1.

The memory device 100 may include the controller 130 configured to store data in at least one of the plurality of memory cells MC11 to MCnm and/or read data stored in each of the plurality of memory cells MC11 to MCnm.

The controller 130 may execute, for example, software (e.g., a program) to control at least another component (e.g., the memory cell array 110) of the memory device 100 and to perform various data processing and/or calculations (or computations). The controller 130 may include a central processing unit, a microprocessor, etc. and may control all operations of the memory device 100. Accordingly, an operation which is performed by the memory device 100 may be understood as being performed under control of the controller 130.

The controller 130 according to an embodiment may control a read operation and/or a write operation of the memory device 100 by using commands CMD, addresses ADDR, and an external power PWR provided from an outside.

Herein, the addresses ADDR may include a row address XADD for selecting one memory cell or one word line and a column address YADD for selecting one memory cell.

Accordingly, for example, in response to a write command among the commands CMD, the controller 130 may store data in at least one memory cell (e.g., the first memory cell MC11) specified by the addresses ADDR from among the plurality of memory cells MC11 to MCnm.

The memory device 100 may include the row decoder 141 connected to the memory cell array 110 through the plurality of word lines WL1 to WLm.

In detail, the row decoder 141 may decode the row address XADD to activate a word line corresponding to the row address XADD from among the plurality of word lines WL1 to WLm.

Herein, for example, the row decoder 141 may include a plurality of word line drivers which are respectively connected to the plurality of word lines WL1 to WLm. However, for another example, the plurality of word line drivers may be implemented as a component independent of the row decoder 141 and may be connected to the row decoder 141 and the plurality of word lines WL1 to WLm.

The memory device 100 may include the column decoder 142 configured to select at least one of the plurality of read bit lines RBL1 to RBLm, the plurality of first write bit lines WBL1 to WBLn, and the plurality of second write bit lines WBLB1 to WBLBn.

For example, in a write operation on the first memory cell MC11, the column decoder 142 may decode the column address YADD to activate the (1-1)-th write bit line WBL1 and the (2-1)-th write bit line WBLB1 corresponding to each other.

For another example, in a read operation on the first memory cell MC11, the column decoder 142 may decode the column address YADD to activate the first read bit line RBL1.

The memory device 100 may include a plurality of read circuits RC1 to RCn and a plurality of write circuits WC1 to WCn which are connected between the column decoder 142 and the memory cell array 110.

In detail, the memory device 100 may include the plurality of read circuits RC1 to RCn, each of which is connected between the column decoder 142 and a corresponding one of the plurality of read bit lines RBL1 to RBLn.

For example, the memory device 100 may include a first read circuit RC1 connected between the column decoder 142 and the first read bit line RBL1.

The controller 130 according to an embodiment may read data stored in the plurality of memory cells MC11 to MCnm by obtaining voltages output from the plurality of memory cells MC11 to MCnm through the plurality of read circuits RC1 to RCn.

For example, the controller 130 may obtain a voltage (or a signal) transferred through the first read bit line RBL1 by using the first read circuit RC1. In addition, based on the voltage obtained by using the first read circuit RC1, the controller 130 may read data stored in at least one (e.g., the first memory cell MC11) of memory cells connected to the first read bit line RBL1.

The memory device 100 may include the plurality of write circuits WC1 to WCn which are connected between the column decoder 142 and the plurality of first and second write bit lines WBL1 to WBLn and WBLB1 to WBLBn.

For example, the memory device 100 may include a first write circuit WC1 which is connected between the column decoder 142 and the (1-1)-th and (2-1)-th write bit lines WBL1 and WBLB1.

The controller 130 may apply a signal for storing data in each of the plurality of memory cells MC11 to MCnm through the plurality of write circuits WC1 to WCn.

For example, the controller 130 may apply a signal for storing data in a memory cell (e.g., the first memory cell MC11) connected to the (1-1)-th write bit line WBL1 and the (2-1)-th write bit line WBLB1 through the first write circuit WC1.

Referring to FIG. 2, a first memory cell MC11A according to an embodiment may include a first inverter INV1, a second inverter INV2, a write buffer WB, and a latch circuit LT. Herein, the first memory cell MC11A illustrated in FIG. 2 may be understood as an example of the first memory cell MC11 illustrated in FIG. 1.

According to an embodiment, the first memory cell MC11A may include the first inverter INV1 including a first PMOS transistor PT1 and a first NMOS transistor NT1 connected in series.

In detail, the first inverter INV1 may include the first PMOS transistor PT1, and the first NMOS transistor NT1 connected between the first PMOS transistor PT1 and a ground.

According to an embodiment, each of the first PMOS transistor PT1 and the first NMOS transistor NT1 may receive an inverse row selection signal LSSB being an inverted version of a row selection signal LSS through a gate electrode thereof.

In detail, each of the first PMOS transistor PT1 and the first NMOS transistor NT1 may receive the inverse row selection signal LSSB being an inverted version of the row selection signal LSS applied to a first word line WL1 connected to the first memory cell MC11A, through the gate electrode thereof.

The controller 130 may apply the inverse row selection signal LSSB to the gate electrode of each of the first PMOS transistor PT1 and the first NMOS transistor NT1.

The first PMOS transistor PT1 may receive a first column selection signal CS1 through a source-drain electrode thereof.

In detail, the first PMOS transistor PT1 may receive the first column selection signal CS1 applied through the (1-1)-th write bit line WBL1, through the source-drain electrode not connected to the first NMOS transistor NT1.

The controller 130 may apply the first column selection signal CS1 to the source-drain electrode of the first PMOS transistor PT1.

In addition, the first inverter INV1 may output a first enable signal EN1, based on the inverse row selection signal LSSB and the first column selection signal CS1. In detail, the first inverter INV1 may output the first enable signal EN1 through a node between the first PMOS transistor PT1 and the first NMOS transistor NT1, based on the inverse row selection signal LSSB and the first column selection signal CS1.

For example, the first inverter INV1 may output the first enable signal EN1 of a logic high level, in response to the first column selection signal CS1 of the logic high level and the inverse row selection signal LSSB of a logic low level.

The first memory cell MC11A may include the second inverter INV2 including a second PMOS transistor PT2 and a second NMOS transistor NT2 connected in series.

In detail, the second inverter INV2 may include the second NMOS transistor NT2, and the second PMOS transistor PT2 connected between the second NMOS transistor NT2 and a power supply voltage VDD.

According to an embodiment, each of the second PMOS transistor PT2 and the second NMOS transistor NT2 may receive the row selection signal LSS through a gate electrode thereof.

In detail, each of the second PMOS transistor PT2 and the second NMOS transistor NT2 may receive the row selection signal LSS applied to the first word line WL1, through the gate electrode thereof.

The controller 130 may apply the row selection signal LSS to the gate electrode of each of the second PMOS transistor PT2 and the second NMOS transistor NT2.

The second NMOS transistor NT2 may receive a second column selection signal CS2 through a source-drain electrode.

In detail, the second NMOS transistor NT2 may receive the second column selection signal CS2 applied through the (2-1)-th write bit line WBLB1, through the source-drain electrode not connected to the second PMOS transistor PT2.

The controller 130 may apply the second column selection signal CS2 to the source-drain electrode of the second NMOS transistor NT2.

In addition, the second inverter INV2 may output a second enable signal EN2, based on the row selection signal LSS and the second column selection signal CS2. In detail, the second inverter INV2 may output the second enable signal EN2 through a node between the second PMOS transistor PT2 and the second NMOS transistor NT2, based on the row selection signal LSS and the second column selection signal CS2.

For example, the second inverter INV2 may output the second enable signal EN2 of the logic high level, in response to the second column selection signal CS2 of the logic high level and the row selection signal LSS of the logic high level.

The first memory cell MC11A may include the write buffer WB connected to the first inverter INV1 and the second inverter INV2.

According to an embodiment, the write buffer WB may include a third PMOS transistor PT3 and a third NMOS transistor NT3 connected in series between the power supply voltage VDD and the ground.

The write buffer WB may output first data D1, based on the first enable signal EN1 output from the first inverter INV1 and the second enable signal EN2 output from the second inverter INV2.

In detail, the third PMOS transistor PT3 may receive the second enable signal EN2 through a gate electrode thereof. The third NMOS transistor NT3 may receive the first enable signal EN1 through a gate electrode thereof.

For example, the third PMOS transistor PT3 may receive the second enable signal EN2 of the logic high level through the gate electrode thereof. The third NMOS transistor NT3 may receive the first enable signal EN1 of the logic high level through the gate electrode thereof.

According to the above description, the third PMOS transistor PT3 may be turned off, and the third NMOS transistor NT3 may be turned on. Accordingly, a first node N1 between the third PMOS transistor PT3 and the third NMOS transistor NT3 may be connected to the ground. That is, the write buffer WB may output the first data D1 of the logic low level (e.g., “0”), in response to the first enable signal EN1 of the logic high level and the second enable signal EN2 of the logic high level.

The write buffer WB may output the first data D1 whose value is determined by the first enable signal EN1 and the second enable signal EN2, through the first node N1 between the third PMOS transistor PT3 and the third NMOS transistor NT3.

The first memory cell MC11A may include the latch circuit LT configured to store the first data D1 output from the write buffer WB.

The latch circuit LT may include a fourth PMOS transistor PT4, a fifth PMOS transistor PT5, a fourth NMOS transistor NT4, and a fifth NMOS transistor NT5 connected in series between the power supply voltage VDD and the ground.

The latch circuit LT may include a sixth PMOS transistor PT6 and a sixth NMOS transistor NT6 connected in series between the power supply voltage VDD and the ground.

The fourth PMOS transistor PT4 may receive the first enable signal EN1 through a gate electrode thereof. The fifth NMOS transistor NT5 may receive the second enable signal EN2 through a gate electrode thereof.

Each of the sixth PMOS transistor PT6 and the sixth NMOS transistor NT6 may receive the first data D1 through a gate electrode thereof.

Each of the fifth PMOS transistor PT5 and the fifth NMOS transistor NT5 may receive first inverse data DB1 output through a second node N2 between the sixth PMOS transistor PT6 and the sixth NMOS transistor NT6, through a gate electrode thereof.

Herein, the first inverse data DB1 may be understood as data obtained by inverting the first data D1. That is, for example, when a value of the first data D1 is “0”, a value of the first inverse data DB1 may be “1”.

According to an embodiment, the latch circuit LT may store the first data D1 output from the write buffer WB.

For example, while the row selection signal LSS of the logic low level, the inverse row selection signal LSSB of the logic high level, the first column selection signal CS1 of the logic low level, and the second column selection signal CS2 of the logic high level are applied to the first memory cell MC11A, the latch circuit LT may maintain the value of the first data D1 output from the write buffer WB.

Herein, for example, an operation in which the latch circuit LT maintains the value of the first data D1 previously output from the write buffer WB may be named a retention operation.

Based on the above configuration, the controller 130 according to an embodiment may apply column selection signals (e.g., the first column selection signal CS1 and the second column selection signal CS2) to source-drain electrodes of transistors PT1, NT2.

Herein, a diffusion capacitance of the source-drain electrode of each transistor may be relatively smaller than a gate capacitance of the gate electrode.

That is, compared to a case where the controller 130 applies the column selection signal to the gate electrode of the transistor, in a case where the controller 130 applies the column selection signal to the source-drain electrode of the transistor according to an embodiment, the controller 130 may reduce a capacitance of an electrical path through which the column selection signal is applied.

The controller 130 according to an embodiment may apply each of column selection signals (e.g., the first column selection signal CS1 and the second column selection signal CS2) to one source-drain electrode in a memory cell.

That is, compared to a case where the controller 130 applies the column selection signal (e.g., the first column selection signal CS1) to each of a plurality of gate electrodes, in a case where the controller 130 applies the column selection signal to one source-drain electrode according to an embodiment, the controller 130 may reduce power which is consumed to apply the column selection signal.

Through the above configuration, the memory device 100 (or the controller 130) according to an embodiment of the present disclosure may improve power efficiency of the write operation on the memory cell (e.g., the first memory cell MC11A).

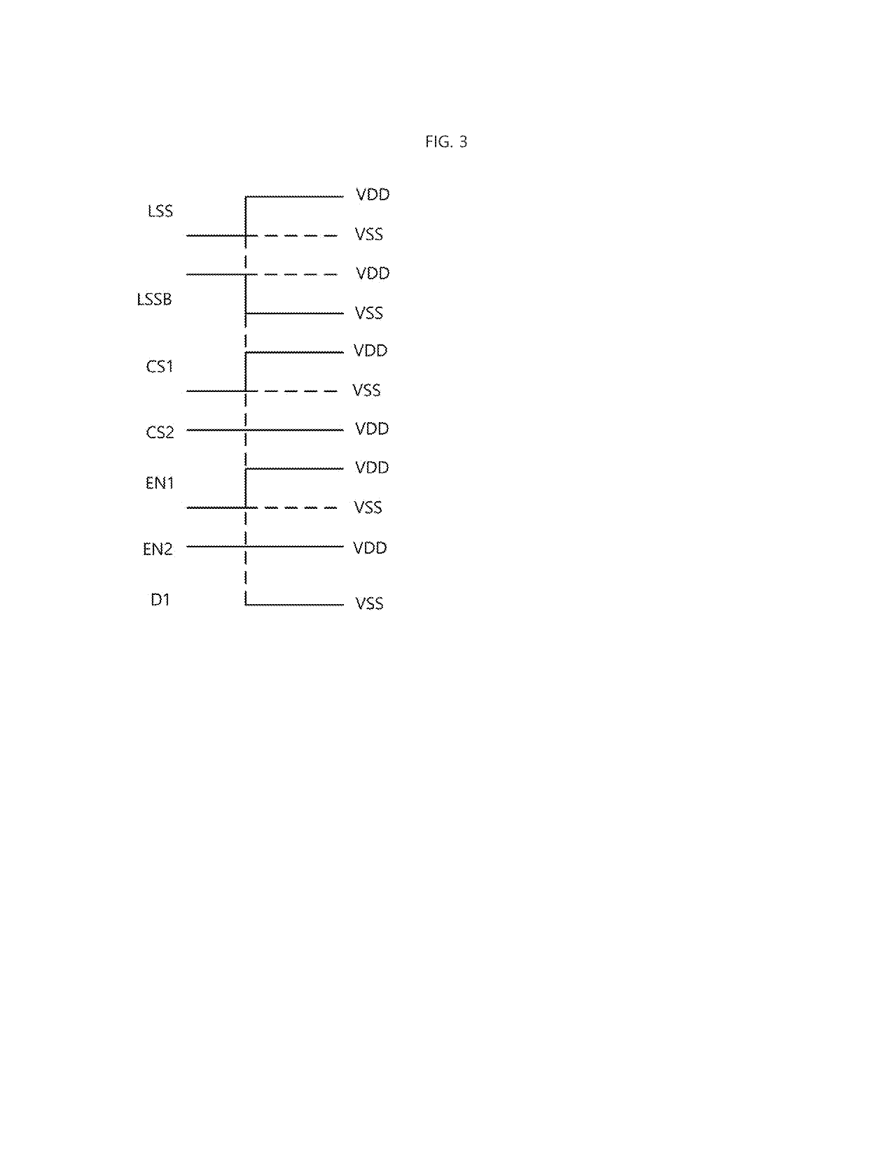

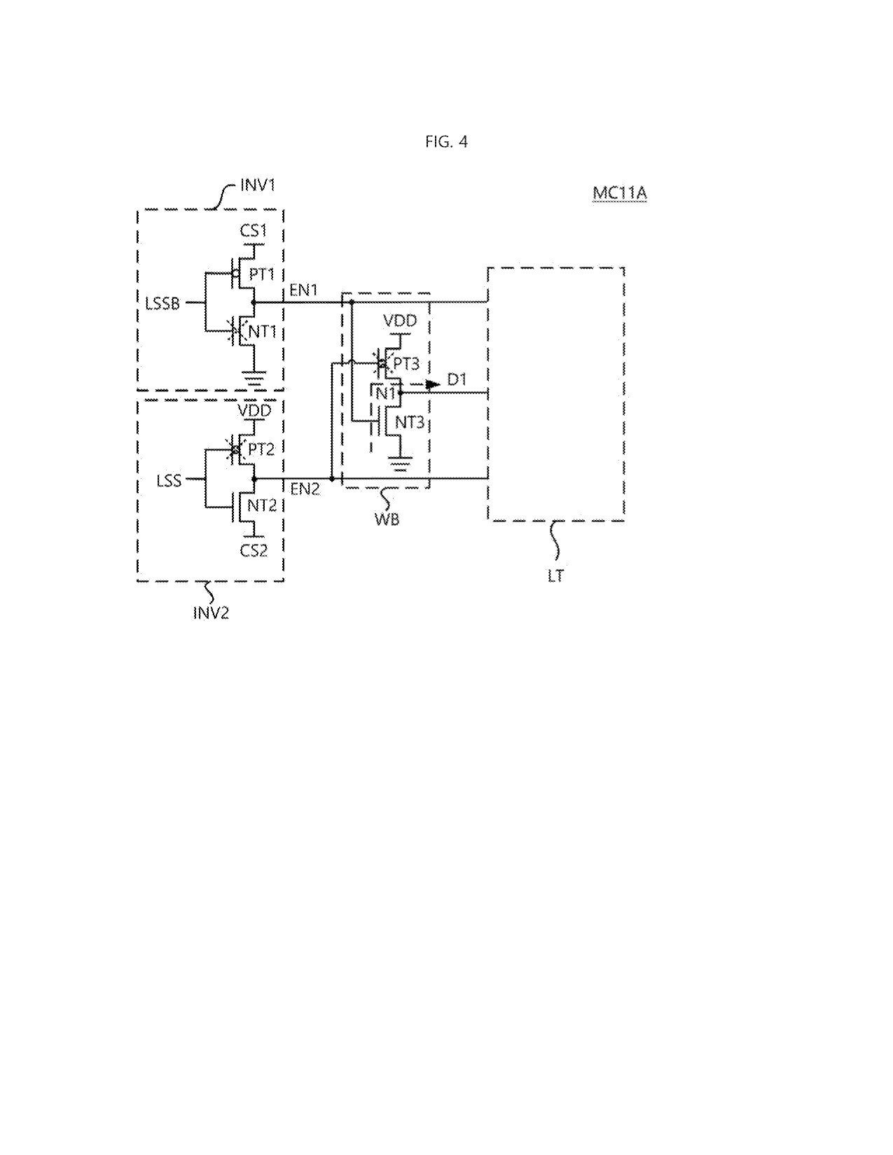

FIG. 3 illustrates signals generated in a write operation on a first memory cell according to an embodiment. FIG. 4 illustrates a configuration in which first data are stored in a first memory cell according to an embodiment.

Referring to FIGS. 3 and 4 together, the controller 130 (or the memory device 100) according to an embodiment may store the first data D1 in the first memory cell MC11A.

Herein, the first memory cell MC11A illustrated in FIG. 4 may be understood as being substantially identical in configuration to the first memory cell MC11A illustrated in FIG. 2. Accordingly, components which are the same or substantially the same as the above components are denoted by the same reference numerals/signs, and thus, additional description will be omitted to avoid redundancy.

According to an embodiment, the controller 130 may apply the inverse row selection signal LSSB of the logic low level (e.g., a ground voltage VSS) to the gate electrode of each of the first PMOS transistor PT1 and the first NMOS transistor NT1. The controller 130 may apply the first column selection signal CS1 of the logic high level to the source-drain electrode of the first PMOS transistor PT1.

In this case, the first PMOS transistor PT1 may be turned on, and the first NMOS transistor NT1 may be turned off.

Accordingly, the first inverter INV1 may output the first enable signal EN1 of the logic high level, in response to the inverse row selection signal LSSB of the logic low level and the first column selection signal CS1 of the logic high level.

The controller 130 may apply the row selection signal LSS of the logic high level to the gate electrode of each of the second PMOS transistor PT2 and the second NMOS transistor NT2. The controller 130 may apply the second column selection signal CS2 of the logic high level (e.g., the power supply voltage VDD) to the source-drain electrode of the second NMOS transistor NT2.

In this case, the second PMOS transistor PT2 may be turned off, and the second NMOS transistor NT2 may be turned on.

Accordingly, the second inverter INV2 may output the second enable signal EN2 of the logic high level, in response to the row selection signal LSS of the logic high level and the second column selection signal CS2 of the logic high level.

In addition, the third PMOS transistor PT3 of the write buffer WB may be turned off in response to the second enable signal EN2 of the logic high level received through the gate electrode thereof. The third NMOS transistor NT3 of the write buffer WB may be turned on in response to the first enable signal EN1 of the logic high level received through the gate electrode thereof. In this case, the first node N1 may be connected to the ground through the third NMOS transistor NT3.

According to an example embodiment, the write buffer WB may output the first data D1 whose value is “0”, through the first node N1 in response to the first enable signal EN1 of the logic high level and the second enable signal EN2 of the logic high level.

In addition, the latch circuit LT may store the first data D1 output from the write buffer WB.

For example, while the row selection signal LSS of the logic low level, the inverse row selection signal LSSB of the logic high level, the first column selection signal CS1 of the logic low level, and the second column selection signal CS2 of the logic high level are applied to the first memory cell MC11A, the latch circuit LT may maintain the value of the first data D1 output from the write buffer WB.

That is, the controller 130 may store the first data D1 (e.g., “0”) in the first memory cell MC11A by using the row selection signal LSS, the first column selection signal CS1, and the second column selection signal CS2.

Based on the above configuration, the controller 130 according to an embodiment may apply the first column selection signal CS1 to the source-drain electrode of the first PMOS transistor PT1. The controller 130 may apply the second column selection signal CS2 to the source-drain electrode of the second NMOS transistor NT2.

Herein, the diffusion capacitance of the source-drain electrode of each transistor may be relatively smaller than the gate capacitance of the gate electrode.

That is, compared to a case where the controller 130 applies the column selection signal to the gate electrode of the transistor, in a case where the controller 130 applies the column selection signal to the source-drain electrode of the transistor according to an embodiment, the controller 130 may reduce a capacitance of an electrical path through which the column selection signal is applied.

The controller 130 according to an embodiment may apply a column selection signal (e.g., the first column selection signal CS1) to one source-drain electrode in a memory cell.

Accordingly, compared to a case where the controller 130 applies the column selection signal (e.g., the first column selection signal CS1) to each of a plurality of gate electrodes, the controller 130 according to an embodiment may apply the column selection signal to one source-drain electrode and thus may reduce the power which is consumed to apply the column selection signal.

The controller 130 according to an embodiment may activate the first memory cell MC11A among the plurality of memory cells by using column selection signals (e.g., the first column selection signal CS1 and the second column selection signal CS2) and the row selection signal LSS.

Herein, a value of data (e.g., the first data D1) stored in the first memory cell MC11A may be determined based on the first enable signal EN1 and the second enable signal EN2 generated by the column selection signals (e.g., the first column selection signal CS1 and the second column selection signal CS2) and the row selection signal LSS.

That is, the controller 130 may control the value of the data stored in the first memory cell MC11A by activating the first memory cell MC11A by using the column selection signals (e.g., the first column selection signal CS1 and the second column selection signal CS2) and the row selection signal LSS.

Accordingly, compared to a case of independently applying a signal for activating a memory cell and a signal for controlling a value of data, the controller 130 according to an embodiment of the present disclosure may store data in a memory cell with a relatively small power.

In other words, the memory device 100 (or the controller 130) according to an embodiment of the present disclosure may improve power efficiency of the write operation on the memory cell (e.g., the first memory cell MC11A).

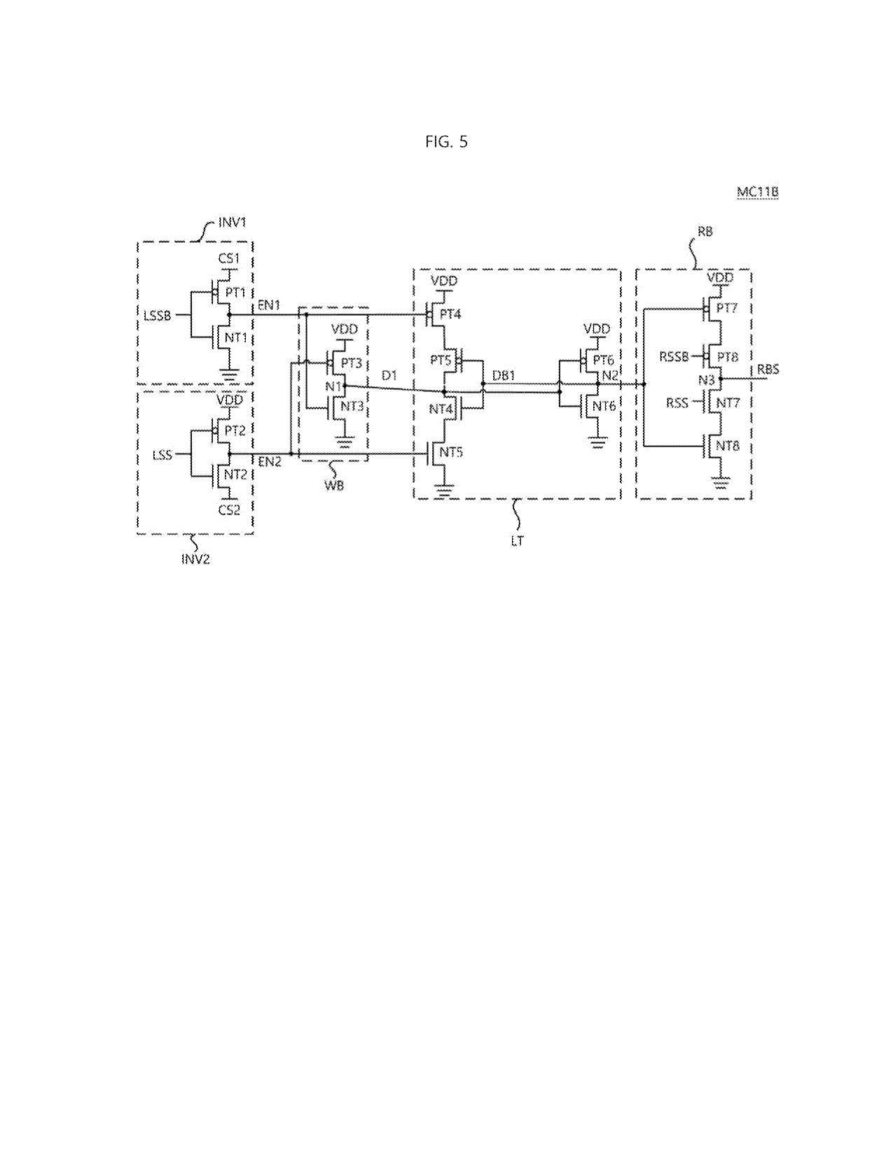

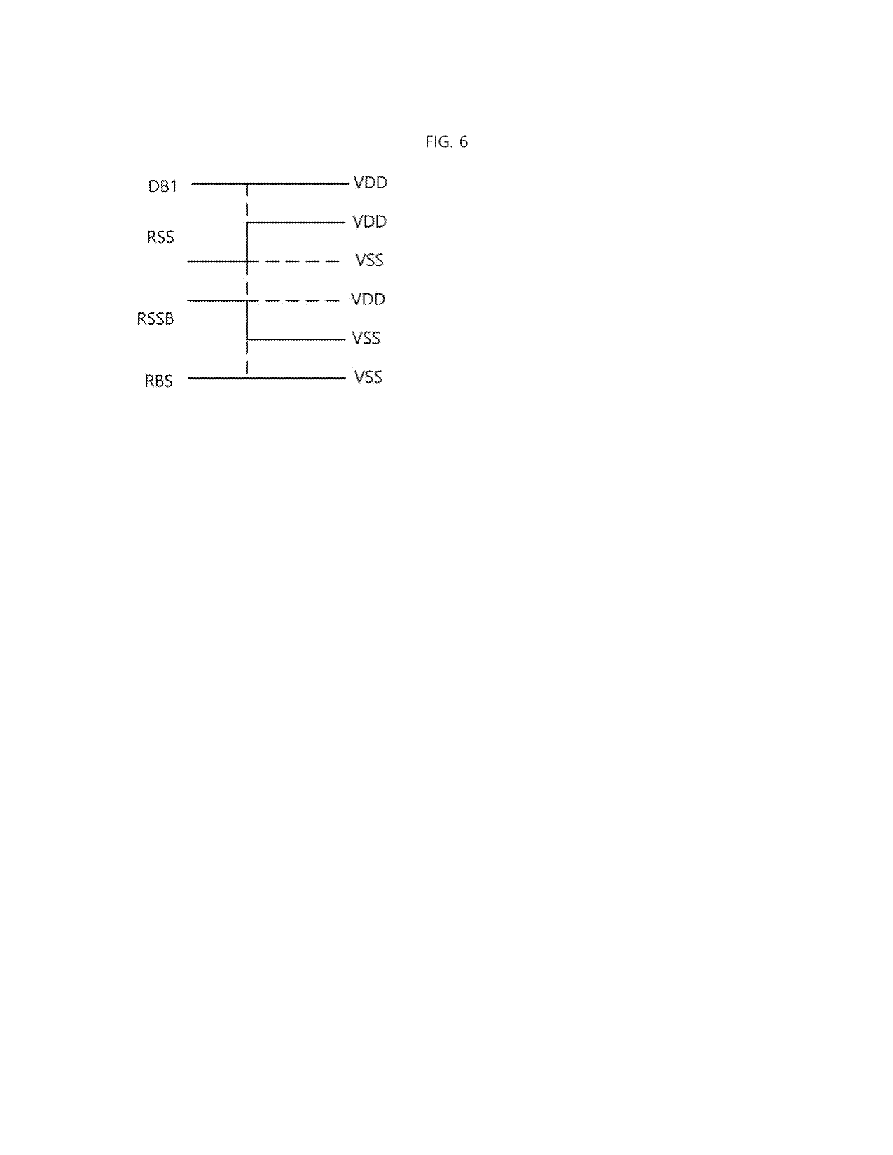

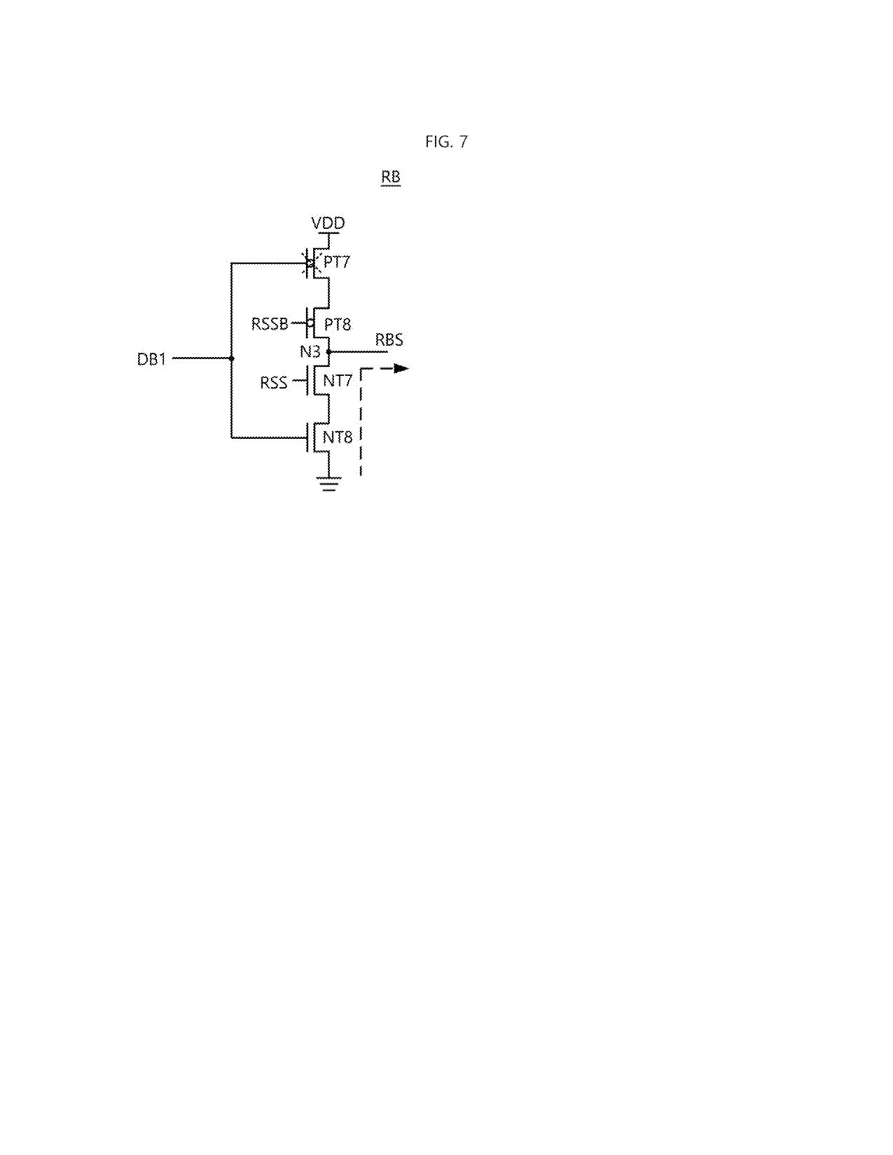

FIG. 5 is a circuit diagram of a first memory cell further including a read buffer according to an embodiment. FIG. 6 illustrates signals generated in a read operation on a first memory cell according to an embodiment. FIG. 7 illustrates a configuration in which first data stored in a first memory cell are output through a read buffer according to an embodiment.

Referring to FIG. 5, a first memory cell MC11B according to an embodiment may include the first inverter INV1, the second inverter INV2, the write buffer WB, the latch circuit LT, and a read buffer RB.

Herein, the first memory cell MC11B illustrated in FIG. 5 may be understood as an example of the first memory cell MC11 illustrated in FIG. 1. The first memory cell MC11B illustrated in FIG. 5 may be understood as further including the read buffer RB in addition to the components of the first memory cell MC11A illustrated in FIG. 2. Accordingly, components which are the same or substantially the same as the above components are denoted by the same reference numerals/signs, and thus, additional description will be omitted to avoid redundancy.

According to an embodiment, the first memory cell MC11B may include the read buffer RB connected to the latch circuit LT.

The read buffer RB may include a seventh PMOS transistor PT7, an eighth PMOS transistor PT8, a seventh NMOS transistor NT7, and an eighth NMOS transistor NT8 connected in series between the power supply voltage VDD and the ground.

Each of the seventh PMOS transistor PT7 and the eighth NMOS transistor NT8 may receive the first inverse data DB1 through a gate electrode thereof. In detail, each of the seventh PMOS transistor PT7 and the eighth NMOS transistor NT8 may receive the first inverse data DB1 stored in the latch circuit LT through the gate electrode thereof.

Herein, the first inverse data DB1 may be understood as data obtained by inverting the first data D1. That is, for example, when a value of the first data D1 is “0”, a value of the first inverse data DB1 may be “1”.

Referring to FIGS. 6 and 7 together, when the value of the first inverse data DB1 is “1”, the seventh PMOS transistor PT7 may be turned off, and the eighth NMOS transistor NT8 may be turned on.

The seventh NMOS transistor NT7 may receive a read selection signal RSS through a gate electrode thereof.

In detail, the controller 130 may apply the read selection signal RSS to the gate electrode of the seventh NMOS transistor NT7.

For example, referring to FIGS. 6 and 7 together, the controller 130 may apply the read selection signal RSS of the logic high level to the gate electrode of the seventh NMOS transistor NT7. Herein, the seventh NMOS transistor NT7 may be turned on by the read selection signal RSS of the logic high level.

The eighth PMOS transistor PT8 may receive an inverse read selection signal RSSB through a gate electrode thereof. Herein, the inverse read selection signal RSSB may be understood as a signal obtained by inverting the read selection signal RSS. That is, for example, when a value of the read selection signal RSS is “1”, a value of the inverse read selection signal RSSB may be “0”.

In detail, the controller 130 may apply the inverse read selection signal RSSB to the gate electrode of the eighth PMOS transistor PT8.

For example, referring to FIGS. 6 and 7 together, the controller 130 may apply the inverse read selection signal RSSB of the logic low level to the gate electrode of the eighth PMOS transistor PT8. Herein, the seventh PMOS transistor PT8 may be turned on by the inverse read selection signal RSSB of the logic low level.

Accordingly, a third node N3 between the eighth PMOS transistor PT8 and the seventh NMOS transistor NT7 may be connected to the ground. That is, the read buffer RB may output a read bit line signal RBS of the logic low level through the third node N3.

That is, the read buffer RB may output the read bit line signal RBS, which is obtained by inverting the first inverse data DB1, in response to the read selection signal RSS of the logic high level and the inverse read selection signal RSSB of the logic low level.

Herein, the read bit line signal RBS may have a logic level corresponding to the value of the first data D1. For example, when the value of the first data D1 is “0”, the read bit line signal RBS may have the logic low level.

Accordingly, the controller 130 may determine the first data D1, based on the read bit line signal RBS output from the read buffer RB.

For example, when the read bit line signal RBS output from the read buffer RB is at the logic low level, the controller 130 may determine that the first data D1 whose value is “0” are stored in the first memory cell MC11B. That is, the controller 130 may apply the read selection signal RSS to the read buffer RB to read the first data D1 stored in the first memory cell MC11B.

Based on the above configuration, the controller 130 according to an embodiment may apply the read selection signal RSS of the logic high level to the first memory cell MC11B to read data (e.g., the first data D1) stored in the first memory cell MC11B.

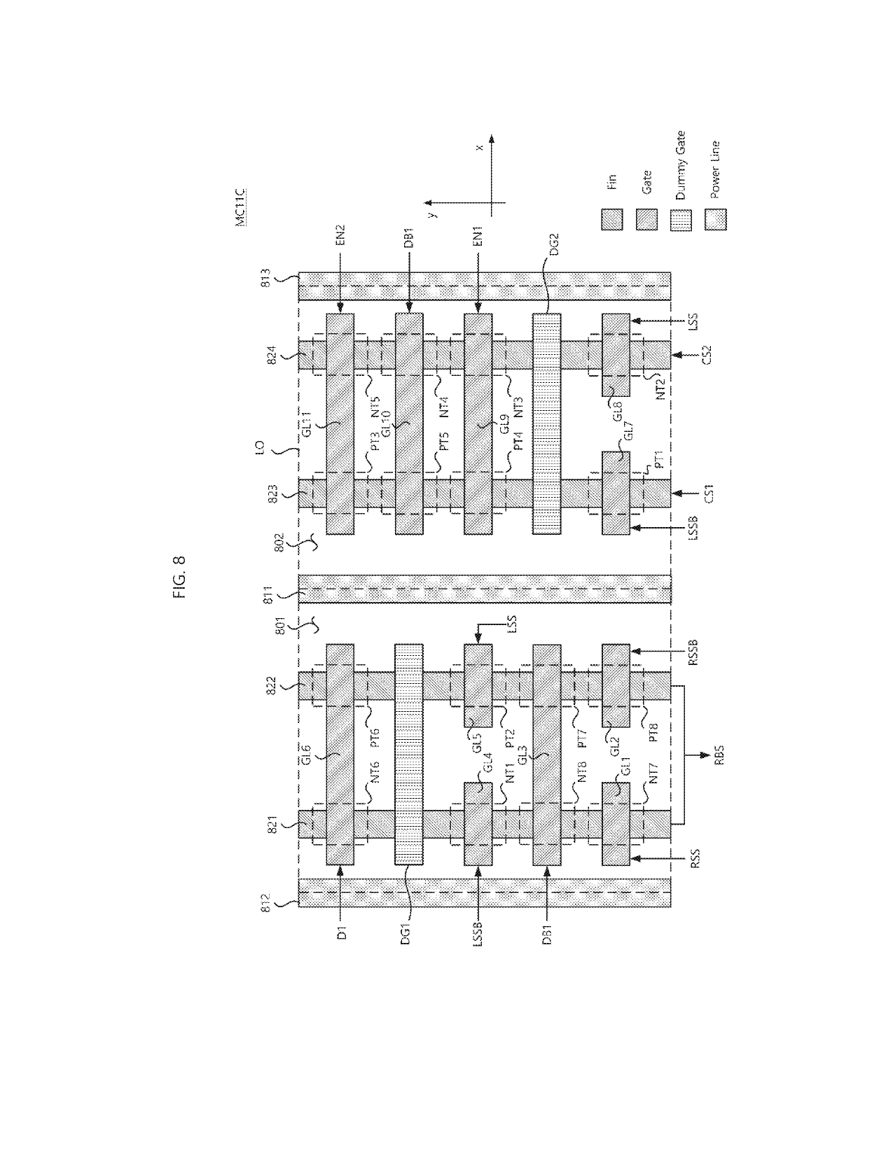

FIG. 8 illustrates a layout of a first memory cell according to an embodiment.

Referring to FIG. 8, a layout LO of a first memory cell MC11C according to an embodiment may include a first area 801 and a second area 802. In detail, the layout LO of the first memory cell MC11C may include the first area 801 and the second area 802 formed adjacent to each other.

Herein, the first memory cell MC11C illustrated in FIG. 8 may be understood as an example of the first memory cell MC11 illustrated in FIG. 1.

According to an embodiment, the layout LO may include a first power line 811, a second power line 812, and a third power line 813 which extend in a first direction (e.g., a y-direction) and are spaced apart from each other in a second direction (e.g., an x-direction).

In detail, the layout LO may include the first power line 811 extending in the first direction at a boundary at which the first area 801 and the second area 802 that are adjacent to each other. The layout LO may include the second power line 812 extending in the first direction at an edge parallel to an edge of the first area 801, which is adjacent to the second area 802. The layout LO may include the second power line 812 extending in the first direction at a first edge of the first area 801 parallel to a second edge of the first area 801, which is adjacent to the second area 802

In addition, the layout LO may include the third power line 813 extending in the first direction at an edge parallel to an edge of the second area 802, which is adjacent to the first area 801. The layout LO may include the third power line 813 extending in the first direction at a first edge of the second area 802 parallel to a second edge of the second area 802, which is adjacent to the first area 801

The first area 801 may be defined as an area between the first power line 811 and the second power line 812. The second area 802 may be defined as an area between the first power line 811 and the third power line 813.

That is, the layout LO of the first memory cell MC11C may include the areas 801 and 802 between the first power line 811, the second power line 812, and the third power line 813. Accordingly, the layout LO of the first memory cell MC11C may be named a multi-column layout including areas between three or more power lines. For example, the layout LO of the first memory cell MC11C may be a 2-column layout including two areas 801 and 802 between three power lines 811, 812, and 813.

According to an embodiment, the controller 130 may apply one of the power supply voltage VDD or the ground voltage VSS to each of the first power line 811, the second power line 812, and the third power line 813.

In detail, the controller 130 may apply the power supply voltage VDD to a power line, which is disposed adjacent to PMOS transistors (e.g., the first PMOS transistor PT1 to the eighth PMOS transistor PT8) from among the first power line 811, the second power line 812, and the third power line 813.

The controller 130 may apply the ground voltage VSS to a power line, which is disposed adjacent to NMOS transistors (e.g., the first NMOS transistor NT1 to the eighth NMOS transistor NT8) from among the first power line 811, the second power line 812, and the third power line 813.

For example, the controller 130 may apply the power supply voltage VDD to the first power line 811. The controller 130 may apply the power supply voltage VDD to an element, which is connected to the first power line 811 from among elements included in the first area 801 and the second area 802, through the first power line 811.

For example, the controller 130 may apply the ground voltage VSS to the second power line 812 and the third power line 813. The controller 130 may apply the ground voltage VSS to an element, which is connected to the second power line 812 and the third power line 813 from among the elements included in the first area 801 and the second area 802, through the second power line 812 and the third power line 813.

However, a magnitude and a kind of a voltage applied to each power line are not limited to the above examples and may be differently determined depending on placements of PMOS transistors and NMOS transistors.

For another example, when NMOS transistors are disposed adjacent to the first power line 811, the controller 130 may apply the ground voltage VSS to the first power line 811. When PMOS transistors are disposed adjacent to the second power line 812 and the third power line 813, the controller 130 may apply the power supply voltage VDD to the second power line 812 and the third power line 813.

According to an embodiment, the plurality of transistors PT1 to PT8 and NT1 to NT8 included in the first memory cell MC11C may be implemented within the first area 801 and the second area 802.

In detail, the first area 801 may include a first pin line 821 and a second pin line 822 each extending in the first direction (e.g., the y-direction). The first area 801 may include a first gate line GL1 to a sixth gate line GL6 each extending in the second direction (e.g., the x-direction). The first area 801 may further include a first dummy gate DG1 extending in the second direction.

Accordingly, the first NMOS transistor NT1, the second PMOS transistor PT2, the sixth PMOS transistor PT6, the sixth NMOS transistor NT6, the seventh PMOS transistor PT7, the seventh NMOS transistor NT7, the eighth PMOS transistor PT8, and the eighth NMOS transistor NT8 may be implemented by the first gate line GL1 to the sixth gate line GL6, the first pin line 821, and the second pin line 822 included in the first area 801.

For example, the first NMOS transistor NT1 may be implemented by the fourth gate line GL4 and at least a partial area of the first pin line 821. Herein, the gate electrode of the first NMOS transistor NT1 may correspond to an area in which the fourth gate line GL4 and the first pin line 821 overlap each other.

For another example, the second PMOS transistor PT2 may be implemented by the fifth gate line GL5 and at least a partial area of the second pin line 822. Herein, the gate electrode of the second PMOS transistor PT2 may correspond to an area in which the fifth gate line GL5 and the second pin line 822 overlap each other.

The second area 802 may include a third pin line 823 and a fourth pin line 824 each extending in the first direction (e.g., the y-direction). The second area 802 may include a seventh gate line GL7 to an eleventh gate line GL11 each extending in the second direction (e.g., the x-direction). The second area 802 may further include a second dummy gate DG2 extending in the second direction.

Accordingly, the first NMOS transistor PT1, the second NMOS transistor NT2, the third PMOS transistor PT3, the third NMOS transistor NT3, the fourth PMOS transistor PT4, the fourth NMOS transistor NT4, the fifth PMOS transistor PT5, and the fifth NMOS transistor NT5 may be implemented by the seventh gate line GL7 to the eleventh gate line GL11, the third pin line 823, and the fourth pin line 824 included in the second area 802.

For example, the first PMOS transistor PT1 may be implemented by the seventh gate line GL7 and at least a partial area of the third pin line 823. Herein, the gate electrode of the first PMOS transistor PT1 may correspond to an area in which the seventh gate line GL7 and the third pin line 823 overlap each other.

For another example, the fourth NMOS transistor NT4 may be implemented by the tenth gate line GL10 and at least a partial area of the fourth pin line 824. Herein, the gate electrode of the fourth NMOS transistor NT4 may correspond to an area in which the tenth gate line GL10 and the fourth pin line 824 overlap each other.

Herein, each of the first pin line 821 to the fourth pin line 824 may be implemented with a metal line. Each of the first gate line GL1 to the eleventh gate line GL11 may be formed of polysilicon.

Herein, each of the plurality of transistors PT1 to PT8 and NT1 to NT8 may be connected to at least one of the first power line 811 to the third power line 813, but for convenience of description, the connection is omitted in drawings.

According to an embodiment, in the write operation on the first memory cell MC11C, the controller 130 may apply a column selection signal and a row selection signal to at least one of the seventh gate line GL7 to the eleventh gate line GL11, the third pin line 823, and the fourth pin line 824 included in the second area 802.

For example, in the write operation on the first memory cell MC11C, the controller 130 may apply the first column selection signal CS1 to the third pin line 823. That is, the controller 130 may apply the first column selection signal CS1 to the source-drain electrode of the first PMOS transistor PT1.

In the write operation on the first memory cell MC11C, the controller 130 may apply the second column selection signal CS2 to the fourth pin line 824. That is, the controller 130 may apply the second column selection signal CS2 to the source-drain electrode of the second NMOS transistor NT2.

In the write operation on the first memory cell MC11C, the controller 130 may apply the inverse row selection signal LSSB to the fourth gate line GL4 and the seventh gate line GL7. That is, the controller 130 may apply the inverse row selection signal LSSB to the gate electrode of each of the first PMOS transistor PT1 and the first NMOS transistor NT1.

In the write operation on the first memory cell MC11C, the controller 130 may apply the row selection signal LSS to the fifth gate line GL5 and the eighth gate line GL8. That is, the controller 130 may apply the row selection signal LSS to the gate electrode of each of the second PMOS transistor PT2 and the second NMOS transistor NT2.

According to an embodiment, in the read operation on the first memory cell MC11C, the controller 130 may determine data stored in the first memory cell MC11C, based on the read bit line signal RBS output from at least one of the first pin line 821 and the second pin line 822.

For example, in the read operation on the first memory cell MC11C, the controller 130 may apply the read selection signal RSS to the first gate line GL1. That is, in the read operation on the first memory cell MC11C, the controller 130 may apply the read selection signal RSS to the gate electrode of the seventh NMOS transistor NT7.

In the read operation on the first memory cell MC11C, the controller 130 may apply the inverse read selection signal RSSB to the second gate line GL2. That is, in the read operation on the first memory cell MC11C, the controller 130 may apply the inverse read selection signal RSSB to the gate electrode of the eighth PMOS transistor PT8.

In addition, the controller 130 may obtain the read bit line signal RBS output from at least one of the first pin line 821 and the second pin line 822.

Herein, the read bit line signal RBS may have a logic level corresponding to a value of data stored in the first memory cell MC11C. For example, when the value of the first data D1 stored in the first memory cell MC11C is “0”, the read bit line signal RBS may have the logic low level.

Accordingly, the controller 130 may obtain the data stored in the first memory cell MC11C, based on the logic level of the read bit line signal RBS.

That is, the controller 130 may apply signals to the plurality of transistors PT1 to PT8 and NT1 to NT8 included in the first area 801 and the second area 802 to control the write operation and the read operation on the first memory cell MC11C.

According to an embodiment, the layout LO of the first memory cell MC11C may be implemented in a shape of a 2-column layout including two areas 801 and 802.

Accordingly, compared to a case where the first memory cell MC11C is implemented in a shape of a 1-column layer, the first memory cell MC11C according to an embodiment of the present disclosure may be implemented with a pin line (or a metal line) of a relatively short length.

The first memory cell MC11C according to an embodiment may share the first pin line 821 to the fourth pin line 824 with an adjacent memory cell. For example, the first memory cell MC11C may share pin lines with an adjacent memory cell through four nodes.

Accordingly, compared to a case where the first memory cell MC11C is implemented in a shape of a 1-column layout in which pin lines are shared with an adjacent memory cell through two nodes, the first memory cell MC11C according to an embodiment of the present disclosure may share pin lines through relatively more nodes.

That is, compared to a case where the first memory cell MC11C is implemented in the shape of the 1-column layout, a capacitance of an electrical path in the first memory cell MC11C according to an embodiment of the present disclosure, through which a signal for the write operation and/or the read operation is applied, may have a relatively small value.

Through the above configuration, the controller 130 (or the memory device 100) according to an embodiment of the present disclosure may reduce power consumption in the write operation and/or the read operation on the first memory cell MC11C.

Based on the above configuration, the controller 130 according to an embodiment may apply column selection signals (e.g., the first column selection signal CS1 and the second column selection signal CS2) to source-drain electrodes of transistors.

Herein, the diffusion capacitance of the source-drain electrode of each transistor may be relatively smaller than the gate capacitance of the gate electrode.

That is, compared to a case where the controller 130 applies the column selection signal to the gate electrode of the through transistor, in a case where the controller 130 applies the column selection signal to the source-drain electrode of the transistor according to an embodiment, the controller 130 may reduce the capacitance of an electrical path through which the column selection signal is applied.

The controller 130 according to an embodiment may apply each of column selection signals (e.g., the first column selection signal CS1 and the second column selection signal CS2) to one source-drain electrode in a memory cell.

That is, compared to a case where the controller 130 applies the column selection signal (e.g., the first column selection signal CS1) to each of a plurality of gate electrodes, in a case where the controller 130 according to an embodiment of the present disclosure applies the column selection signal to one source-drain electrode, the controller 130 may reduce the power which is consumed to apply the column selection signal.

This means that the memory device 100 (or the controller 130) according to an embodiment of the present disclosure may improve power efficiency of the write operation on the memory cell (e.g., the first memory cell MC11C).

As described above, the controller 130 according to an embodiment of the present disclosure may apply column selection signals (e.g., the first column selection signal CS1 and the second column selection signal CS2) to source-drain electrodes of transistors.

Herein, the diffusion capacitance of the source-drain electrode of each transistor may be relatively smaller than the gate capacitance of the gate electrode.

That is, compared to a case where the controller 130 applies the column selection signal to the gate electrode of the through transistor, in a case where the controller 130 according to an embodiment of the present disclosure applies the column selection signal to the source-drain electrode of the transistor, the controller 130 may reduce the capacitance of an electrical path through which the column selection signal is applied.

The controller 130 according to an embodiment may apply each of column selection signals (e.g., the first column selection signal CS1 and the second column selection signal CS2) to one source-drain electrode in a memory cell.

That is, compared to a case where the controller 130 applies a column selection signal (e.g., the first column selection signal CS1) to each of a plurality of gate electrodes, in a case where the controller 130 applies the column selection signal to one source-drain electrode, the controller 130 may reduce the power which is consumed to apply the column selection signal.

This means that the memory device 100 (or the controller 130) according to an embodiment of the present disclosure may improve power efficiency of the write operation on the memory cell (e.g., the first memory cell MC11).

A memory device according to an embodiment of the present disclosure may improve power efficiency of a write operation on a memory cell.

While the present disclosure has been described with reference to example embodiments thereof, it will be apparent to those of ordinary skill in the art that various changes and modifications may be made thereto without departing from the spirit and scope of the present disclosure as set forth in the following claims and their equivalents.

What is claimed is:

1. A memory device comprising:
a memory cell array comprising a plurality of memory cells; and
a controller connected to the memory cell array,
wherein a first memory cell among the plurality of memory cells comprises:
a first inverter comprising a first PMOS transistor, and a first NMOS transistor connected between the first PMOS transistor and a ground;
a second inverter comprising a second NMOS transistor, and a second PMOS transistor connected between the second NMOS transistor and a power supply voltage;
a write buffer configured to generate first data, based on a first enable signal output from the first inverter and a second enable signal output from the second inverter; and
a latch circuit configured to store the first data, and
wherein, in a write operation on the first memory cell, the controller is configured to apply a first column selection signal to a source-drain electrode of the first PMOS transistor.

2. The memory device of claim 1, wherein, in the write operation on the first memory cell, the controller is configured to apply a second column selection signal to a source-drain electrode of the second NMOS transistor.

3. The memory device of claim 2, wherein, in the write operation on the first memory cell, the controller is configured to:
apply a row selection signal to a gate electrode of each of the second PMOS transistor and the second NMOS transistor; and
apply an inverse row selection signal, obtained by inverting the row selection signal, to a gate electrode of each of the first PMOS transistor and the first NMOS transistor.

4. The memory device of claim 2, wherein the write buffer comprises:
a third PMOS transistor connected to the power supply voltage and configured to receive the second enable signal through a gate electrode thereof; and
a third NMOS transistor connected between the third PMOS transistor and the ground and configured to receive the first enable signal through a gate electrode thereof.

5. The memory device of claim 4, wherein the latch circuit comprises:
a fourth PMOS transistor, a fifth PMOS transistor, a fourth NMOS transistor, and a fifth NMOS transistor connected in series between the power supply voltage and the ground; and
a sixth PMOS transistor and a sixth NMOS transistor connected in series between the power supply voltage and the ground.

6. The memory device of claim 5, wherein the fourth PMOS transistor is configured to receive the first enable signal through a gate electrode thereof,
wherein the fifth NMOS transistor is configured to receive the second enable signal through a gate electrode thereof,
wherein each of the sixth PMOS transistor and the sixth NMOS transistor is configured to receive the first data through a gate electrode thereof, and
wherein each of the fifth PMOS transistor and the fourth NMOS transistor is configured to receive first inverse data, output from a second node between the sixth PMOS transistor and the sixth NMOS transistor, through a gate electrode thereof.

7. The memory device of claim 6, further comprising:
a read buffer connected to the latch circuit,
wherein the read buffer comprises a seventh PMOS transistor, an eighth PMOS transistor, a seventh NMOS transistor, and an eighth NMOS transistor connected in series between the power supply voltage and the ground, and
wherein each of the seventh PMOS transistor and the eighth NMOS transistor is configured to receive the first inverse data, output from the latch circuit, through a gate electrode thereof.

8. The memory device of claim 7, wherein, in a read operation on the first memory cell, the controller is configured to:
apply a read selection signal to a gate electrode of the seventh NMOS transistor;
apply an inverse read selection signal, obtained by inverting the read selection signal, to a gate electrode of the eighth PMOS transistor; and
determine the first data, based on a read bit line signal output from the read buffer, in response to the read selection signal and the inverse read selection signal.

9. The memory device of claim 3, wherein the first inverter is configured to output the first enable signal of a logic high level, in response to the first column selection signal of the logic high level and the inverse row selection signal of a logic low level,
wherein the second inverter is configured to output the second enable signal of the logic high level, in response to the second column selection signal of the logic high level and the row selection signal of the logic high level, and
wherein the write buffer is configured to output the first data of the logic low level, in response to the first enable signal and the second enable signal.

10. A memory cell comprising:
a first inverter comprising a first PMOS transistor, and a first NMOS transistor connected between the first PMOS transistor and a ground;
a second inverter comprising a second NMOS transistor, and a second PMOS transistor connected between the second NMOS transistor and a power supply voltage;
a write buffer configured to generate first data, based on a first enable signal output from the first inverter and a second enable signal output from the second inverter; and
a latch circuit configured to store the first data, based on the first enable signal and the second enable signal,
wherein the first inverter is configured to output the first enable signal, in response to a first column selection signal and an inverse row selection signal, and
wherein the first column selection signal is applied through a source-drain electrode of the first PMOS transistor.

11. The memory cell of claim 10, wherein the second inverter is configured to output the second enable signal, in response to a second column selection signal and a row selection signal obtained by inverting the inverse row selection signal, and
wherein the second column selection signal is applied through a source-drain electrode of the second NMOS transistor.

12. The memory cell of claim 11, wherein the inverse row selection signal is applied to a gate electrode of each of the first PMOS transistor and the first NMOS transistor, and
wherein the row selection signal is applied to a gate electrode of each of the second PMOS transistor and the second NMOS transistor.

13. The memory cell of claim 10, wherein the write buffer comprises:
a third PMOS transistor connected to the power supply voltage and configured to receive the second enable signal through a gate electrode thereof; and
a third NMOS transistor connected between the third PMOS transistor and the ground and configured to receive the first enable signal through a gate electrode thereof.

14. The memory cell of claim 10, further comprising:
a read buffer configured to receive, from the latch circuit, first inverse data obtained by inverting the first data,
wherein the read buffer is configured to output a read bit line signal corresponding to the first data, based on the first inverse data, in response to a read selection signal and an inverse read selection signal obtained by inverting the read selection signal.

15. The memory cell of claim 11, wherein the first inverter is configured to output the first enable signal of a logic high level, in response to the first column selection signal of the logic high level and the inverse row selection signal of a logic low level,
wherein the second inverter is configured to output the second enable signal of the logic high level, in response to the second column selection signal of the logic high level and the row selection signal of the logic high level, and
wherein the write buffer is configured to output the first data of the logic low level, in response to the first enable signal and the second enable signal.

16. A memory device comprising:
a first memory cell; and
a controller electrically connected to the first memory cell,
wherein the first memory cell comprises:
a first inverter comprising a first PMOS transistor, and a first NMOS transistor connected between the first PMOS transistor and a ground;
a second inverter comprising a second NMOS transistor, and a second PMOS transistor connected between the second NMOS transistor and a power supply voltage;
a write buffer configured to generate first data, based on a first enable signal output from the first inverter and a second enable signal output from the second inverter; and
a latch circuit configured to store the first data,
wherein, in a write operation on the first memory cell, the controller is configured to apply a first column selection signal to a source-drain electrode of the first PMOS transistor and apply a second column selection signal to a source-drain electrode of the second NMOS transistor.

17. The memory device of claim 16, wherein, in the write operation on the first memory cell, the controller is configured to:
apply a row selection signal to a gate electrode of each of the second PMOS transistor and the second NMOS transistor; and
apply an inverse row selection signal, obtained by inverting the row selection signal, to a gate electrode of each of the first PMOS transistor and the first NMOS transistor.

18. The memory device of claim 17, wherein the first inverter is configured to output the first enable signal of a logic high level, in response to the first column selection signal of the logic high level and the inverse row selection signal of a logic low level,
wherein the second inverter is configured to output the second enable signal of the logic high level, in response to the second column selection signal of the logic high level and the row selection signal of the logic high level, and
wherein the write buffer is configured to output the first data of the logic low level, in response to the first enable signal of the logic high level and the second enable signal of the logic high level.

19. The memory device of claim 16, wherein the write buffer comprises:
a third PMOS transistor connected to the power supply voltage and configured to receive the second enable signal through a gate electrode thereof; and
a third NMOS transistor connected between the third PMOS transistor and the ground and configured to receive the first enable signal through a gate electrode thereof.

20. The memory device of claim 16, further comprising:
a read buffer configured to receive, from the latch circuit, first inverse data obtained by inverting the first data,
wherein the read buffer is configured to output a read bit line signal corresponding to the first data, based on the first inverse data, in response to a read selection signal and an inverse read selection signal obtained by inverting the read selection signal.
